(19) United States
(12) Patent Application Publication
(10) Pub. No.: US 2014/0285182 A1
(43) Pub. Date: Sep. 25, 2014

(54) Accu Volt Meter

(71) Applicant: Javier Rojas, JR., Chicago, IL (US)

(72) Inventor: Javier Rojas, JR., Chicago, IL (US)

(21) Appl. No.: 14/219,950

(22) Filed: Mar. 19, 2014

Related U.S. Application Data
(60) Provisional application No. 61/803,409, filed on Mar. 19, 2013.

(51) Int. Cl. G01R 13/02

(52) U.S. Cl. CPC G01R 13/02
USPC 324/149

(57) ABSTRACT

The invention provides a handheld digital voltmeter approximately the size and shape of a ballpoint pen. When its tip is placed on a live electrical wire, the Accu Volt Meter digitally displays a voltage reading on a small LCD screen and audibly states the voltage reading through an incorporated data to voice software program and a tiny incorporated speaker.

### CLAIM OF PRIORITY

This patent application claims priority under 35 USC 119(e)(1) from U.S. Provisional Patent Application Ser. No. 61/803,409 filed Mar. 19, 2013, of common inventorship herewith entitled, “Accu Volt Meter.”

### FIELD OF THE INVENTION

The present invention pertains to the field of electrical engineering, and more specifically to the field of handheld, digital voltmeters.

### BACKGROUND OF THE INVENTION

The prior art has put forth several designs for compact voltage testers. Among these are:

U.S. Pat. No. 3,829,776 to Elpidio Lozoya describes a relatively compact voltage tester in the form of a pen or pencil adapted to be carried in a shirt pocket or the like and including a tubular casing with a spring biased connecting rod attached to a metallic probe, both being movably mounted in the casing with the probe projecting from one end thereof. The probe is applied to the circuit point to be tested whereupon the voltage appearing thereat is coupled across a selected strip resistor also carried in the casing. The rod is mechanically connected to a sliding contact member positioned against the strip resistor which then acts as a voltage pick off. The selected strip resistor and contact member comprise a potentiometer and are operable such that as the probe is depressed against the spring by pushing the casing toward the circuit point, a neon lamp lights at a certain depressed position. A pointer also coupled to the rod acts in combination with a calibrated scale on the outer surface of the casing to provide a reading of the voltage applied across the potentiometer.

U.S. Pat. No. 5,057,770 to Calvin Kalishman describes a handheld probing device for use in testing existence and amount of electrical potential in an automobile engine block or other object under investigation. The device has a specially formed housing from which extend a probe and ground lead at opposite ends. The housing includes a voltmeter and an electric bulb connected in parallel between the probe and ground lead. The housing includes a switch which enables the device to be operated while held in one hand, enabling the other of the user's hand to be free and usable for other functions.

U.S. Pat. No. 6,617,840 to Walter S. Bierer describes a wireless phasing voltmeter having a high impedance AC voltmeter in series with two high impedance probes. Shielding surrounds and electrically isolates the voltmeter and probes which communicate via wireless FM transmission, thus eliminating the cable customarily used to connect the probes. The transmitted signal may be analog or digital. The transmitter and receiver are plugged into the same jacks the probe uses for the cable. In parallel with the voltmeter and connected electrically with the shielding is an electrical circuit designed to add the capacitive current to a current detected by the probes in such a way that the net effect on the measured current is zero.

None of these prior art references describe the present invention.

### SUMMARY OF THE INVENTION

It is an object of the present invention to provide a lightweight digital voltage testing device for anyone who works with electrical devices, HVAC systems and appliances.

### BRIEF DESCRIPTION OF THE DRAWINGS

FIG. 1 is a perspective side view showing an LCD screen, a voice speaker and a retractable, extendable and flexible tip.

FIG. 2 is a perspective side view showing a battery operated unit with a pen style clip and a removable sensor tip.

FIG. 3 is a perspective side view showing a removable sensor tip, a push button to toggle between AC and DC voltage, and extendable prong tips attached to a cord that plugs into the present invention.

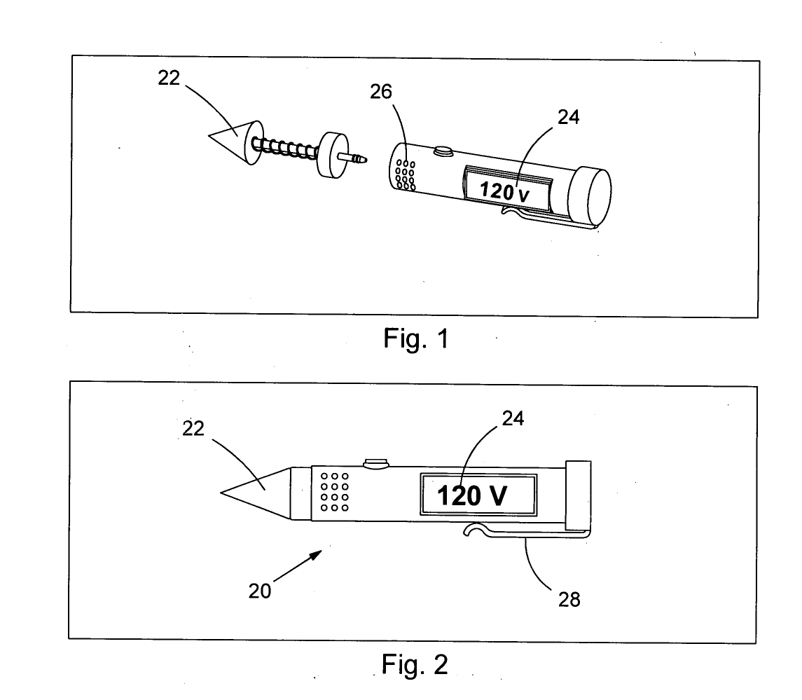

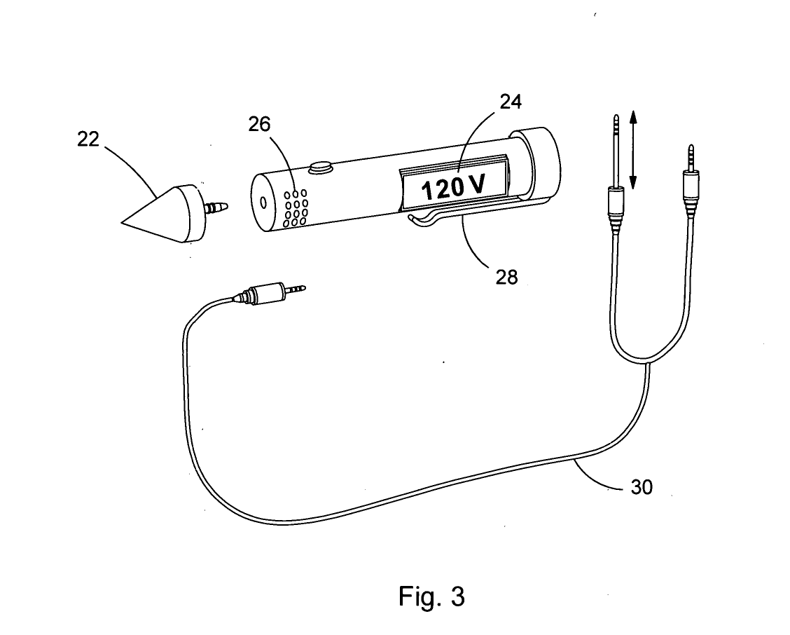

### DETAILED DESCRIPTION OF THE INVENTION

Some inventions, such as a wheel and a personal computer, change the way we live and change the world. These inventions mark milestones in humanity's technological history and bring huge changes in the life of a society. Such groundbreaking inventions are rare. The majority of successful inventions are small improvements which come into play in a gradually subtle manner and bring a heightened individual convenience that spreads to all consumers. Examples include spray pump bottles, cameras with built in flashes, VELCRO™ (hook and loop) fasteners, electric toothbrushes or rubber bands. These simple and creative improvements of existing products make people's lives easier and gradually become fully integrated in their daily lives.

The present invention, hereinafter referred to as the Accu Volt Meter, is a handheld digital voltmeter approximately the size and shape of a ballpoint pen. Please refer to the drawings. When its tip 22 is placed on a live electrical wire, the Accu Volt Meter digitally displays a voltage reading on a small LCD screen 24 and audibly states the voltage reading through an incorporated data to voice software program and a tiny incorporated speaker 26. Lightweight and handy, the Accu Volt Meter is engineered without external wires or probes generally found in voltmeters. The Accu Volt Meter has a pen style pocket clip 28 for easy storage and access, making the present invention an ideal and indispensable tool for anyone who works with electrical devices, systems or appliances.

The Accu Volt Meter comprises an elongate hand held device 20 shaped like a retractable ballpoint pen and comprises a conical tip 22 and cylindrical body measuring approximately five inches in length and three eighths inch in diameter. A compact LCD screen 24 is embedded in the body. A tiny audio speaker 26 and data to voice software is situated beside the LCD screen 24. A battery compartment (not shown) is located in the Accu Volt Meter's proximal end. The pen style pocket clip 28 attached to the device 20 provides convenient storage and pocket access. The extendable and flexible tip 22 provides easy access to tight and hard to reach places. This tip 22 is removable, so a user may attach a two prong tip 30 to measure readings on any Electronic Range Control or ERC board. Except for the distal end of its tip, the Accu Volt Meter, is constructed in an insulating plastic or rubber coated plastic.

Using the present invention is simple. The user turns on the Accu Volt Meter with a button located over the battery compartment at its proximal or upper end. The user then touches the tip of the device to a live current carrying wire. The Accu Volt Meter ascertains a voltage, displays a reading on the LCD screen and audibly states that voltage through a microprocessor controlled speaker.

Electricians, automotive mechanics, electronics workers and household do it yourselfers will appreciate the compact convenience and ease of use provided by the Accu Volt Meter. No larger than a ballpoint pen and conveniently clipped to a shirt pocket, the present invention provides technicians with a simple and immediate means of checking a circuit's voltage.

Although this invention has been described with respect to specific embodiments, it is not intended to be limited thereto and various modifications which will become apparent to the person of ordinary skill in the art are intended to fall within the spirit and scope of the invention as described herein taken in conjunction with the accompanying drawings and the appended claims.

1. A lightweight digital voltage testing device comprising:
an elongate body hand held device shaped like a retractable ballpoint pen comprising a conical tip and cylindrical body, further comprising a compact LCD screen embedded in the body, further comprising an audio speaker and data to voice software situated next to the LCD screen.

2. The device of claim 1, further comprising a battery compartment located in the proximal end of the device.

3. The device of claim 1, further comprising a pocket clip attached to the body of the device providing convenient storage and pocket access.

4. The device of claim 1 wherein the conical tip is extendable and flexible and provides easy access to tight and hard to reach places.

5. The device of claim 4 wherein the tip is removable, so a user can attach a two prong tip to measure readings on any Electronic Range Control or ERC board.

6. the device of claim 1 wherein the device excluding the distal end of the tip, is constructed in an insulating plastic or rubber coated plastic.

7. The device of claim 4 measuring approximately five inches in length and three eighths inch in diameter.
